(19) United States
(12) Patent Application Publication
(10) Pub. No.: US 2026/0033140 A1
(43) Pub. Date: Jan. 29, 2026

(54) DISPLAY PANEL AND DISPLAY DEVICE

(71) Applicant: Hubei Yangtze Industrial Innovation Center of Advanced Display Co., LTD., Wuhan (CN)

(72) Inventors: Xiao CHI, Wuhan (CN); Huifang ZHOU, Wuhan (CN)

(21) Appl. No.: 18/826,570

(22) Filed: Sep. 6, 2024

(30) Foreign Application Priority Data
Jul. 23, 2024 (CN) 202410994298.6

(51) Int. Cl. H10K 59/122; H10K 59/35; H10K 59/80

(52) U.S. Cl. CPC H10K 59/122; H10K 59/353; H10K 59/879; H10K 59/8792

(57) ABSTRACT

A display panel and a display device are provided. The display panel includes a substrate; a pixel definition layer located at one side of the substrate and including a plurality of openings; a plurality of light-emitting devices corresponding to the plurality of openings one by one and each light-emitting device being at least partially located in a corresponding opening of the plurality of openings; a groove at least passing through the pixel definition layer along a direction perpendicular to a plane where the substrate is located; and a dimming structure located at a side of the pixel definition layer away from the substrate. Along the direction parallel to the plane where the substrate is located, at least one side of the light-emitting device is provided with the groove, and at least one side of the light-emitting device is provided with the dimming structure.

### CROSS-REFERENCE TO RELATED APPLICATION

This application claims the priority of Chinese Patent Application No. 202410994298.6, filed on Jul. 23, 2024, the content of which is incorporated by reference in its entirety.

### TECHNICAL FIELD

The present disclosure generally relates to the field of display technologies and, more particularly, relates to a display panel and a display device.

### BACKGROUND

With the development of display technologies, various display panels, such as organic light-emitting display panels and liquid crystal display panels, etc., have emerged. Among them, organic light-emitting display panels are widely used in mobile phones, computers, notebooks and other electronic devices due to their advantages such as self-luminescence, high brightness, low power consumption and fast response.

Organic light-emitting display panels include common layers, and the common layers of multiple sub-pixels are interconnected, which may cause current to flow from one sub-pixel to another adjacent sub-pixel through the common layer. Such a current is called lateral leakage current, and the lateral leakage current will cause sub-pixels to be bright, affecting the display effect. The present disclosed display panels and display devices are direct to solve such a problem and other problems in the arts.

### SUMMARY

One aspect of the present disclosure provides a display panel. The display panel includes a substrate; a pixel definition layer located at one side of the substrate and including a plurality of openings; a plurality of light-emitting devices corresponding to the plurality of openings one by one and each light-emitting device being at least partially located in a corresponding opening of the plurality of openings; a groove at least passing through the pixel definition layer along a direction perpendicular to a plane where the substrate is located; and a dimming structure located at a side of the pixel definition layer away from the substrate. Along the direction parallel to the plane where the substrate is located, at least one side of the light-emitting device is provided with the groove, and at least one side of the light-emitting device is provided with the dimming structure.

Another aspect of the present disclosure includes a display device. The display device includes a display panel. The display panel includes a substrate; a pixel definition layer located at one side of the substrate and including a plurality of openings; a plurality of light-emitting devices corresponding to the plurality of openings one by one and each light-emitting device being at least partially located in a corresponding opening of the plurality of openings; a groove at least passing through the pixel definition layer along a direction perpendicular to a plane where the substrate is located; and a dimming structure located at a side of the pixel definition layer away from the substrate. Along the direction parallel to the plane where the substrate is located, at least one side of the light-emitting device is provided with the groove, and at least one side of the light-emitting device is provided with the dimming structure.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates an exemplary display panel according to various disclosed embodiments of the present disclosure;

FIG. 2 illustrates an A-A′-sectional of the display panel in FIG. 2;

FIG. 3 illustrates another A-A′-sectional of the display panel in FIG. 2;

FIG. 4 illustrates another exemplary display panel according to various disclosed embodiments of the present disclosure;

FIG. 5 illustrates another exemplary display panel according to various disclosed embodiments of the present disclosure;

FIG. 6 illustrates another exemplary display panel according to various disclosed embodiments of the present disclosure;

FIG. 7 illustrates another exemplary display panel according to various disclosed embodiments of the present disclosure;

FIG. 8 illustrates another exemplary display panel according to various disclosed embodiments of the present disclosure;

FIG. 9 illustrates another exemplary display panel according to various disclosed embodiments of the present disclosure;

FIG. 10 illustrates another exemplary display panel according to various disclosed embodiments of the present disclosure;

FIG. 11 illustrates a B-B′-sectional view of the display panel in FIG. 9;

FIG. 12 illustrates another exemplary display panel according to various disclosed embodiments of the present disclosure;

FIG. 13 illustrates another exemplary display panel according to various disclosed embodiments of the present disclosure;

FIG. 14 illustrates a C-C′-sectional view of the display panel in FIG. 12;

FIG. 15 illustrates another exemplary display panel according to various disclosed embodiments of the present disclosure;

FIG. 16 illustrates a D-D′-sectional view of the display panel in FIG. 15;

FIG. 17 illustrates another exemplary display panel according to various disclosed embodiments of the present disclosure;

FIG. 18 illustrates an E-E′-sectional view of the display panel in FIG. 17;

FIG. 19 illustrates another A-A′-sectional view of the display panel in FIG. 1; and

FIG. 20 illustrates an exemplary display panel according to various disclosed embodiments of the present disclosure.

### DETAILED DESCRIPTION

To more clearly understand the above-mentioned purposes, features and advantages of the present disclosure, the scheme of the present disclosure will be further described below. It should be noted that the embodiments of the present disclosure and the features in the embodiments can be combined with each other without conflict.

In the following description, many specific details are explained to facilitate a full understanding of the present disclosure, but the present disclosure can also be implemented in other ways different from those described herein; obviously, the embodiments in the specification are only part of the embodiments of the present disclosure, not all of them.

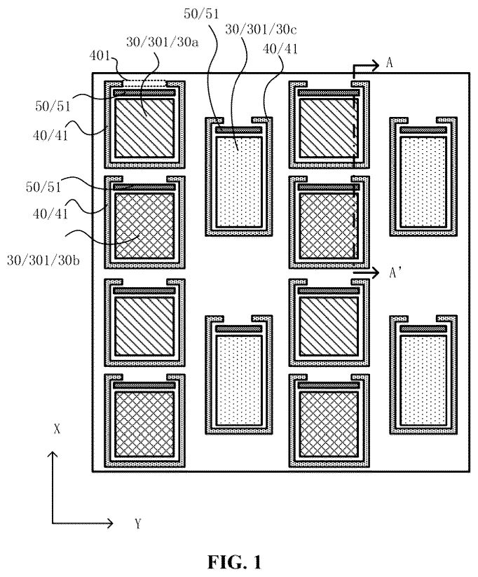

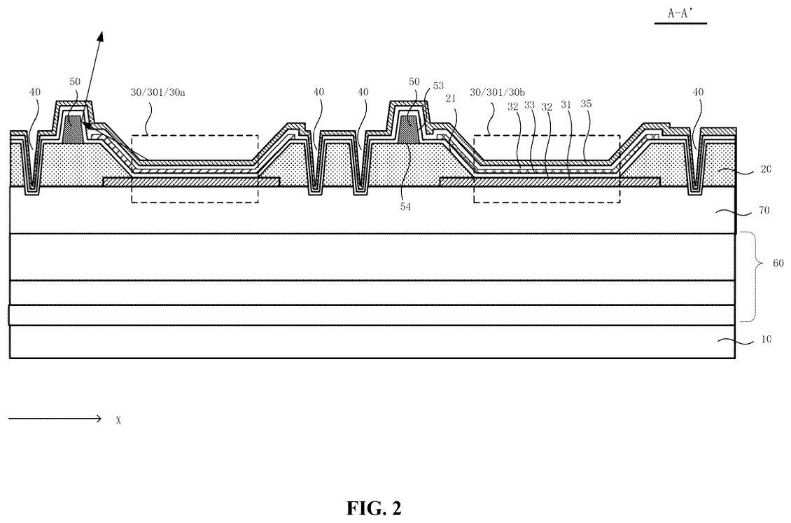

The present disclosure provides a display panel. FIG. 1 is a schematic top view of an exemplary display panel according to various disclosed embodiments of the present disclosure, and FIG. 2 is an A-A′-sectional view of the display panel in FIG. 1. As shown in FIG. 1 and FIG. 2, the display panel may include a substrate 10.

The display panel may also include a pixel definition layer 20. The pixel definition layer 20 may be located on one side of the substrate 10, and the pixel definition layer 20 may include a plurality of openings 21.

Further, the display panel may include a plurality of light-emitting devices 30 corresponding to the plurality of openings 21 one by one. A light-emitting device 30 may be at least partially located in a corresponding opening 21.

Further, the display panel may include a groove 40. Along the direction perpendicular to the plane where the substrate 10 is located, the groove 40 may at least pass through the pixel definition layer 20.

Further, the display panel may include a dimming structure 50. The dimming structure 50 may be located on the side of the pixel definition layer 20 away from the substrate 10. Along the direction parallel to the plane where the substrate 10 is located, at least one side of the light-emitting device 30 may be provided with a groove 40, and at least one side of the light-emitting device 30 may be provided with a dimming structure 50.

Specifically, the display panel provided by one embodiment of the present disclosure may include a substrate 10. The substrate 10 may be a rigid substrate, and the material of the substrate 10 may be glass. The substrate 10 may also be a flexible substrate, and the material of the substrate 10 may include polyimide (PI), polycarbonate (PC), or polyethylene terephthalate (PET), etc. The substrate 10 may be configured to support and protect the film layer formed thereon.

In one embodiment, the display panel may also include an array layer 60 disposed on the substrate 10. The array layer 60 may include a pixel circuit for driving the light-emitting devices 30 to emit light, the pixel circuit may correspond to at least one light-emitting device 30, and the light-emitting device 30 may be electrically connected to the pixel circuit corresponding thereto. For example, the light-emitting device 30 electrically connected to the same pixel circuit may constitute a sub-pixel, or in other words, the pixel circuit and the light-emitting device 30 electrically connected to the pixel circuit together may constitute a sub-pixel, and multiple sub-pixels may display the picture together. For example, if two light-emitting devices 30 are electrically connected to the same pixel circuit, then the two light-emitting devices 30 and the pixel circuit together may constitute a sub-pixel. It should be noted that the specific circuit structure of the pixel circuit can be set by a person skilled in the art according to the actual situation, for example, it may be a 2T1C (two transistors and one capacitor), 7T1C, 8T1C or other circuits in the relevant technology, and the present disclosure does not specifically limit this.

It should be noted that FIG. 1 exemplarily shows an arrangement of the light-emitting devices 30 in the display panel. In other embodiments of the present disclosure, the light-emitting devices 30 in the display panel may also adopt other arrangements, which will not be described in detail in the present disclosure.

It should be noted that FIG. 1 exemplarily shows that the vertical projection pattern of the light-emitting device 30 on the plane where the substrate 10 is located is a rectangle. In other embodiments of the present disclosure, the vertical projection pattern of the light-emitting device 30 on the plane where the substrate 10 is located may also be other shapes, which will not be described in detail in the present disclosure.

The pixel definition layer 20 may be located on one side of the substrate 10. The material of the pixel definition layer 20 may include an insulating material. The pixel definition layer 20 may include a plurality of openings 21. The pixel definition layer 20 may define the light-emitting area through the openings 21. The light-emitting area may be used to set a light-emitting device 30. The light-emitting device 30 may include a first electrode 31, a vapor deposition layer, and a second electrode 34. The vapor deposition layer may be located between the first electrode 31 and the second electrode 34. The first electrode 31 may be a patterned structure that is insulated from each other, and the first electrode 31 may be an anode. The second electrode 34 of each light-emitting device 30 may be connected to each other, and the second electrode 34 may be a common electrode of each light-emitting device 30, and the second electrode 34 may be a cathode.

FIG. 2 exemplarily shows that the first electrode 31 is an anode and the second electrode 34 is a cathode. In other embodiments of the present disclosure, the first electrode 31 may also be a cathode, and the second electrode 34 may also be an anode.

The vapor deposition layer may include a light-emitting layer 33 and a common layer 32. A portion of the common layer 32 may be located between the first electrode 31 and the light-emitting layer 33, and a portion of the common layer 32 may be located between the light-emitting layer 33 and the second electrode 34. The light-emitting layer 33 may be made by evaporation using a fine metal mask (FMM), and the light-emitting layers 33 corresponding to at least some of the light-emitting devices 30 may be separated from each other. In the direction perpendicular to the plane where the substrate 10 is located, the overlapping portions of the first electrode 31, the common layer 32, the light-emitting layer 33 and the second electrode 34 in each light-emitting device 30 may form the light-emitting device 30. The common layer 32 may be made by evaporation using an open mask (common mask), and the common layer 32 corresponding to each light-emitting device 30 may be connected to each other to form a whole surface structure. The common layer 32 may include a hole injection layer (HIL), a hole transport layer (HTL), a hole blocking layer (HBL), an electron blocking layer (EBL), an electron transport layer (ETL), and/or an electron injection layer (EIL), etc.

Because the common layer 32 of each light-emitting device 30 may be interconnected, current may flow from one light-emitting device 30 to another adjacent light-emitting device 30 through the common layer 32, that is, a lateral leakage current may be generated. Accordingly, the light-emitting device 30 that should not emit light may emit light in response to the current flowing from the adjacent light-emitting device 30, resulting in a leaking light problem, which may reduce the display effect of the display panel.

In the display panel provided by the embodiments of the present disclosure, a groove 40 may be provided on at least one side of the light-emitting device 30 in a direction parallel to the plane where the substrate 10 is located, and the groove 40 may at least pass through the pixel definition layer 20 in a direction perpendicular to the plane where the substrate 10 is located. Accordingly, when the common layer 32 is subsequently evaporated, the setting of the groove 40 may increase the path length of the common layer 32, and the inclined surface of the inner wall of the groove 40 may cause the thickness of the common layer 32 to be thinned, and may even cause the common layer 32 to be cut off, thereby effectively hindering the transmission of the lateral leakage current, improving the problem of leaking light of sub-pixels, and improving the display effect.

Along the direction parallel to the plane where the substrate 10 is located, at least one side of the light-emitting device 30 may also be provided with a dimming structure 50, and the dimming structure 50 may be located at the side of the pixel definition layer 20 away from the substrate 10. Accordingly, when the common layer 32 is subsequently evaporated, the portion of the common layer 32 covering the dimming structure 50 may be a raised structure. The setting of the dimming structure 50 may increase the path length of the common layer 32, and the inclined surface of the dimming structure 50 may cause the thickness of the common layer 32 to be thinned, thereby effectively hindering the transmission of the lateral leakage current, reducing the problem of sub-pixel light leaking, and improving the display effect.

At the same time, when the large-angle light emitted by the light-emitting device 30 is directed to the dimming structure 50 adjacent to it, the dimming structure 50 may change the light path of the large-angle light, and the large-angle light may be converted into a small-angle light or a positive-angle light, effectively increasing the number of small-angle light and positive-angle light. Because the user's eye observes the display panel usually in the positive-angle direction or the small-angle direction, the increase in the number of small-angle light and positive-angle light may effectively improve the light-emitting efficiency of the display panel and reduce power consumption. Further, the settings of the dimming structure 50 may effectively reduce the number of large-angle light. Accordingly, users at a large-angle position may not watch the display screen of the display panel, thereby realizing the anti-peeping function.

It should be noted that the positive-angle light may refer to the light emitted in the direction perpendicular to the light-emitting surface of the display panel, the large-angle light may refer to the light with a larger angle with the direction perpendicular to the light-emitting surface of the display panel, and the small-angle light may refer to the light with a smaller angle with the direction perpendicular to the light-emitting surface of the display panel. For example, among the light emitted from the backlight surface of the display panel toward the light-emitting surface of the display panel, the light with an angle greater than 30° with the direction perpendicular to the light-emitting surface of the display panel may be large-angle light, and the light with an angle less than 30° with the direction perpendicular to the light-emitting surface of the display panel may be small-angle light. In other embodiments of the present disclosure, the large and small angles may also be determined based on other angles according to the angle between the light and the direction perpendicular to the light-emitting surface of the display panel, and the present disclosure will not repeat them one by one here. In the relevant embodiments of the present disclosure, the relevant descriptions are applicable, and the present disclosure will not repeat them.

It should be noted that the specific dimensions of the groove 40 and the dimming structure 50 may be set by those skilled in the art according to actual conditions, and no specific limitation is made here.

Further, refer to FIG. 1 and FIG. 2, in some embodiments, the material of the dimming structure 50 may include a reflective material. Therefore, when the large-angle light emitted by the light-emitting device 30 is directed to the dimming structure 50 adjacent to it, the light may be reflected, and the reflected light may be converted into small-angle light or positive-angle light and emitted.

In one embodiment, the material of the dimming structure 50 may include a metal oxide, and exemplarily, the material of the dimming structure 50 may include titanium dioxide. In other embodiments of the present disclosure, the dimming structure 50 may also include other reflective materials, which will not be described in detail in the present disclosure.

Further, referring to FIG. 1 and FIG. 2, in some embodiments, along the direction perpendicular to the plane where the substrate 10 is located, the width of the portion of the groove 40 away from one end of the substrate 10 may be greater than the width of the portion adjacent to one end of the substrate 10. Accordingly, the etching difficulty of the groove 40 may be relatively low, which may effectively reduce the process difficulty and reduce the production cost.

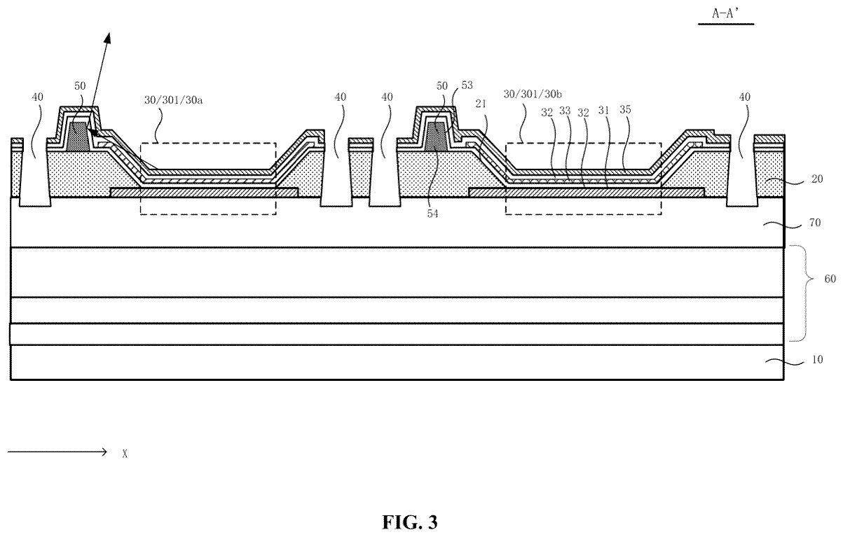

FIG. 3 is another A-A′-sectional view of the display panel described in FIG. 1. As shown in FIG. 3 and referring to FIG. 1, in some embodiments, along a direction perpendicular to the plane where the substrate 10 is located, the width of the portion of the groove 40 away from one end of the substrate 10 is smaller than the width of the portion adjacent to one end of the base substrate 10. Thus, when the common layer 32 is subsequently evaporated, the common layer 32 may be disconnected at the groove 40, thereby cutting off the transmission path of the leakage current in the common layer 32, effectively cutting off the transmission of the lateral leakage current, and being more conducive to reducing the problem of sub-pixel leaking and improving the display effect.

In one embodiment, the display panel may further include a planarization layer 70 disposed between the array layer 60 and the pixel definition layer 20. The groove 40 may pass through the pixel definition layer 20 in the direction perpendicular to the plane where the substrate 10 is located, and the groove 40 may partially pass through the planarization layer 70, which may be conducive to increasing the depth of the groove 40 in a direction perpendicular to the plane where the substrate 10 is located, thereby facilitating increasing the path length of the common layer 32 on the pixel definition layer 20, thereby effectively hindering the transmission of lateral leakage current, reducing the problem of sub-pixel leaking, and improving the display effect.

Further, referring to FIG. 1 and FIG. 2, in some embodiments, at least one groove 40 and/or at least one dimming structure 50 may be provided between two adjacent light-emitting devices 30.

Specifically, the arrangement of the groove 40 and the dimming structure 50 may be conducive to hindering the transmission of lateral leakage current. At least one groove 40 may be arranged between two adjacent light-emitting devices 30, or at least one dimming structure 50 may be arranged between two adjacent light-emitting devices 30, or at least one groove 40 and at least one dimming structure 50 may be arranged between two adjacent light-emitting devices 30, which may effectively block the current from flowing from one of the two adjacent light-emitting devices 30 to the other light-emitting device 30 through the common layer 32, effectively reduce the leakage current, inhibit the light-emitting device 30 that does not need to emit light from the sub-pixel light-leaking phenomenon, and improve the display effect.

In one embodiment, when one groove 40 is arranged between two adjacent light-emitting devices 30, the minimum spacing between the groove 40 and the light-emitting device 30 adjacent to it may be less than the minimum spacing between the groove 40 and another light-emitting device 30. When a dimming structure 50 is arranged between two adjacent light-emitting devices 30, the minimum spacing between the dimming structure 50 and the light-emitting device 30 closest to it may be less than the minimum spacing between the dimming structure 50 and another light-emitting device 30. For example, when a groove 40 is provided between two adjacent light-emitting devices 30, the minimum spacing between the groove 40 and the light-emitting device 30 closest thereto is 1 μm, the minimum spacing between the groove 40 and another light-emitting device 30 may be greater than 1 μm. When a dimming structure 50 is provided between two adjacent light-emitting devices 30, the minimum spacing between the dimming structure 50 and the light-emitting device 30 closest thereto is 1 μm, the minimum spacing between the dimming structure 50 and another light-emitting device 30 may be greater than 1 μm.

Further, referring to FIG. 1 and FIG. 2, in some embodiments, the vertical projection of the groove 40 on the plane where the substrate 10 is located may not overlap with the vertical projection of the dimming structure 50 on the plane where the substrate 10 is located.

Specifically, because the groove 40 may at least pass through the pixel definition layer 20 in the direction perpendicular to the plane where the substrate 10 is located, and the dimming structure 50 may be located at the side of the pixel definition layer 20 away from the substrate 10, the dimming structure 50 may not be provided in the area where the groove 40 is provided in the display panel. The vertical projection of the groove 40 on the plane where the substrate 10 is located may not overlap with the vertical projection of the dimming structure 50 on the plane where the base substrate 10 is located. For example, along the direction perpendicular to the plane where the substrate 10 is located, the groove 40 and the dimming structure 50 may not overlap, that is, the area where the groove 40 is arranged in the display panel and the area where the dimming structure 50 is arranged in the display panel may not overlap such that the arrangement of the groove 40 and the dimming structure 50 in the display panel may not affect each other.

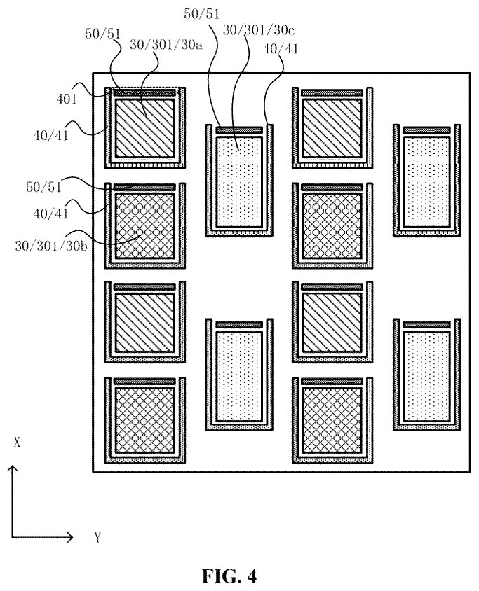

FIG. 4 is a schematic top view of another exemplary display panel provided by the present disclosure. As shown in FIG. 4, in some embodiments, the light-emitting device 30 may include a first light-emitting device 301, a groove 40 located around the first light-emitting device 301 and adjacent to the first light-emitting device 301 may be a first groove 41, and a dimming structure 50 located around the first light-emitting device 301 and adjacent to the first light-emitting device 301 may be a first dimming structure 51. The vertical projections of the first groove 41 and the first dimming structure 51 on the plane where the substrate 10 is located may form an annular structure, and the vertical projection of the first light-emitting device 301 on the plane where the substrate 10 may be located in the annular structure.

Specifically, the light-emitting device 30 may include a first light-emitting device 301. Among them, the groove 40 located around the first light-emitting device 301 and adjacent to the first light-emitting device 301 may be a first groove 41. The “around” mentioned here may refer to at least one side, and the “adjacent to” mentioned here may mean that no other grooves 40 are provided between the two, and no other light-emitting devices 30 are provided between the two. In other words, along the direction parallel to the plane where the substrate 10 is located, the first groove 41 may be arranged at at least one side of the first light-emitting device 301, and no other grooves 40 or other light-emitting devices 30 may be arranged between the first groove 41 and the first light-emitting device 301.

The dimming structure 50 located around the first light-emitting device 301 and adjacent to the first light-emitting device 301 may be the first dimming structure 51. The “around” mentioned here may refer to at least one side, and the “adjacent” mentioned here may mean that no other dimming structure 50 may be arranged between the two, and no other light-emitting device 30 may be arranged between the two. In other words, along the direction parallel to the plane where the substrate 10 is located, the first dimming structure 51 may be arranged at at least one side of the first light-emitting device 301, and no other dimming structure 50 or other light-emitting device 30 may be arranged between the first dimming structure 51 and the first light-emitting device 301.

The vertical projection of the first groove 41 on the plane where the substrate 10 is located and the vertical projection of the first dimming structure 51 on the plane where the substrate 10 is located may form an annular structure, and the vertical projection of the first light-emitting device 301 on the plane where the substrate 10 is located may be located in the annular structure, that is, the structure formed by the first groove 41 and the first dimming structure 51 may surround the first light-emitting device 301, that is, the first light-emitting device 301 may be located in the circle surrounded by the structure formed by the first groove 41 and the first dimming structure 51. Because the arrangement of the groove 40 and the dimming structure 50 may be conducive to hindering the transmission of lateral leakage current, the first groove 41 and the first dimming structure 51 may effectively block the transmission of leakage current between the first light-emitting device 301 and any adjacent light-emitting device 30, thereby improving the display effect.

Moreover, the setting of the first dimming structure 51 may adjust the wide viewing angle light emitted by the first light-emitting device 301, effectively increase the number of small viewing angle light and positive viewing angle light, thereby effectively improving the light-emitting efficiency of the display panel and reducing power consumption. At the same time, the number of wide viewing angle light in the direction where the first dimming structure 51 is set may be reduced, and the anti-peeping display in the direction where the first dimming structure 51 is set may be realized.

It should be noted that the ring structure composed of the vertical projection of the first groove 41 and the first dimming structure 51 on the plane where the substrate 10 is located may be a continuous annular structure (i.e., without a gap) or an intermittent annular structure (i.e., with a gap, as shown in FIG. 1 and FIG. 4, etc.), which will not be described in detail in this disclosure.

Further, referring to FIG. 4, in some embodiments, the light-emitting devices 30 in the display panel may all be the first light-emitting devices 301.

Specifically, each light-emitting device 30 in the display panel may adopt the arrangement of the first groove 41 and the first dimming structure 51 around the first light-emitting device 301 and adjacent to the first light-emitting device 301 such that a groove 40 and/or a dimming structure 50 may be arranged between any two adjacent light-emitting devices 30 in the display panel, which may effectively block the current from flowing from one of the two adjacent light-emitting devices 30 to the other light-emitting device 30 through the common layer 32, effectively reduce the leakage current, and suppress the sub-pixel leaking phenomenon of the light-emitting device 30 that does not need to emit light, thereby improving the display effect.

It should be noted that the naming of the first light-emitting device 301 is only used to distinguish the arrangement of the groove 40 and the dimming structure 50 around the light-emitting device 30 and adjacent to the light-emitting device 30. The arrangement of the first light-emitting device 301 may refer to the conventional arrangement in the art, and the arrangement of the first light-emitting device 301 in the present disclosure does not make special requirements.

Further, referring to FIG. 4, in some embodiments, the vertical projection of the first groove 41 on the plane where the substrate 10 is located may be a semi-annular structure (i.e., U-shaped, [symbol] -shaped) including the first notch 401, and along the first direction X, the first notch 401 may be located at one side of the first light-emitting device 301. The first direction X may be parallel to the plane where the substrate 10 is located.

The vertical projection of the first dimming structure 51 on the plane where the substrate 10 is located may be a stripe structure. Along the first direction X, the first dimming structure 51 and the first notch 401 may be located at the same side of the first light-emitting device 301.

Specifically, the vertical projection of the first dimming structure 51 on the plane where the base substrate 10 is located may be a strip structure, and along the first direction X, the first dimming structure 51 may be located at one side of the first light-emitting device 301. The setting of the first dimming structure 51 may adjust the large viewing angle light emitted by the first light-emitting device 301, may effectively increase the number of small viewing angle light and positive viewing angle light, thereby improving the light extraction efficiency and reducing power consumption. At the same time, the number of large viewing angle light in the first direction X may be reduced, thereby realizing the anti-peeping in the first direction X.

The vertical projection of the first groove 41 on the plane where the substrate 10 is located is a semi-annular structure including the first notch 401. Along the first direction X, the first dimming structure 51 and the first notch 401 may be located at the same side of the first light-emitting device 301, that is, the first groove 41 may not be set in the area around the first light-emitting device 301 in the display panel and where the first dimming structure 51 is set, thereby avoiding the mutual influence between the setting of the first groove 41 and the setting of the first dimming structure 51.

Moreover, the vertical projection of the first groove 41 on the plane where the substrate 10 is located may be a semi-annular structure including the first notch 401. Along the first direction X, the first dimming structure 51 and the first notch 401 may be located at the same side of the first light-emitting device 301, that is, the first groove 41 may be arranged around the first light-emitting device 301 at the other side where the first dimming structure 51 is not arranged. Accordingly, the vertical projection of the first groove 41 on the plane where the substrate 10 is located and the vertical projection of the first dimming structure 51 on the plane where the substrate 10 is located may form an annular structure, and the vertical projection of the first light-emitting device 301 on the plane where the substrate 10 is located may be located in the annular structure, that is, the structure formed by the first groove 41 and the first dimming structure 51 may surround the first light-emitting device 301, and that is, the first light-emitting device 301 may be located in the circle surrounded by the structure formed by the first groove 41 and the first dimming structure 51. Because the arrangement of the groove 40 and the dimming structure 50 may both be conducive to hindering the transmission of lateral leakage current, the first groove 41 and the first dimming structure 51 may effectively block the transmission of leakage current between the first light-emitting device 301 and any adjacent light-emitting device 30, thereby improving the display effect.

It should be noted that the present embodiment exemplarily shows that along the first direction X, the first dimming structure 51 may be arranged at one side of the first light-emitting device 301, and the first groove 41 may be arranged at the other side of the first light-emitting device 301. In other embodiments of the present disclosure, the first dimming structure 51 may also be arranged on the other side of the first light-emitting device 301, or at at least two sides of the first light-emitting device 301. Specifically, the first dimming structure 51 may be arranged according to the dimming effect to be achieved, and accordingly, the first groove 41 may be arranged on the remaining side of the first light-emitting device 301, which may not be described in detail in the present disclosure.

It should be noted that FIG. 4 exemplarily shows that the vertical projection of the first dimming structure 51 on the plane where the substrate 10 is located is a linear strip structure. In other embodiments of the present disclosure, the vertical projection of the first dimming structure 51 on the plane where the substrate 10 is located may also be a non-linear strip structure, and the present disclosure does not specifically limit this.

Further, referring to FIG. 1, in some embodiments, the length of the first dimming structure 51 along the second direction Y may be greater than the length of the first notch 401 along the second direction Y, and along the first direction X, the first notch 401 may be located at the side of the first dimming structure 51 away from the first light-emitting device 301. The first direction X and the second direction Y may intersect. In one embodiment, the first direction X and the second direction Y may be perpendicular to each other.

Specifically, the vertical projection of the first groove 41 on the plane where the base substrate 10 is located may be a semi-annular structure including the first notch 401, that is, the groove 40 may not be provided at the position corresponding to the first notch 401, along the first direction X, the first dimming structure 51 and the first notch 401 may be located at the same side of the first light-emitting device 301, the length of the first dimming structure 51 along the second direction Y may be greater than the length of the first notch 401 along the second direction Y, and along the second direction Y, the two ends of the first dimming structure 51 may be respectively located on both sides of the first notch 401. Accordingly, the first dimming structure 51 may effectively block the leakage current from being transmitted through the portion of the common layer 32 corresponding to the first notch 401, further reducing the leakage current and improving the display effect.

Along the first direction X, the first notch 401 may be located at the side of the first dimming structure 51 away from the first light-emitting device 301, that is, relative to the first notch 401, the spacing between the first dimming structure 51 and the first light-emitting device 301 may be smaller, that is, the first dimming structure 51 may be closer to the first light-emitting device 301, which may be more conducive to the first dimming structure 51 to adjust the light emitted by the first light-emitting device 301.

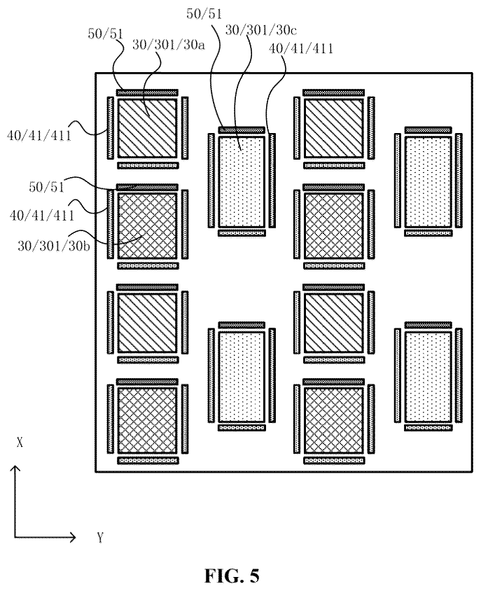

FIG. 5 is a planar schematic diagram of another exemplary display panel provided by the present disclosure. As shown in FIG. 5, in some embodiments, the first groove 41 may include a plurality of mutually isolated first sub-sections 411, and the vertical projection of the first sub-section 411 on the plane where the substrate 10 is located may be a strip structure.

Along the first direction X, a first dimming structure 51 and a first sub-section 411 may be respectively located at the opposite sides of the first light-emitting device 301, and along the second direction Y, two first sub-sections 411 may be respectively located on the opposite sides of the first light-emitting device 301. The first direction X and the second direction Y may intersect. In one embodiment, the first direction X and the second direction Y may be perpendicular to each other.

Specifically, the first groove 41 may include a plurality of first sub-portions 411 that are separated from each other, that is, the first sub-sections 411 in the first groove 41 may not connected to each other, and the first sub-portions 411 may be designed to be spaced from each other. Among them, along the first direction X, a first dimming structure 51 and a first sub-portion 411 may be respectively located at opposite sides of the first light-emitting device 301 such that a first dimming structure 51 and a first sub-portion 411 may be arranged between two adjacent first light-emitting devices 301 along the first direction X, which may effectively block the transmission of leakage current between two adjacent first light-emitting devices 301 along the first direction X, thereby improving the display effect. Along the second direction Y, the two first sub-portions 411 may be respectively located at opposite sides of the first light-emitting device 301 such that two first sub-portions 411 may be arranged between two adjacent first light-emitting devices 301 along the second direction Y, thereby effectively blocking the transmission of leakage current between two adjacent first light-emitting devices 301 along the second direction Y, thereby improving the display effect.

At the same time, because the first sub-portions 411 are not connected to each other and are designed to be spaced apart from each other, the first sub-portions 411 may be configured to have a strip structure in the vertical projection on the plane where the substrate 10 is located, which is beneficial to simplify the process difficulty of the first groove 41 and effectively reduce production costs.

It should be noted that FIG. 5 exemplarily shows that the vertical projection of the first sub-portion 411 on the plane where the substrate 10 is located is a linear strip structure. In other embodiments of the present disclosure, the vertical projection of the first sub-portion 411 on the plane where the substrate 10 is located may also be a non-linear strip structure, and the present disclosure does not specifically limit this.

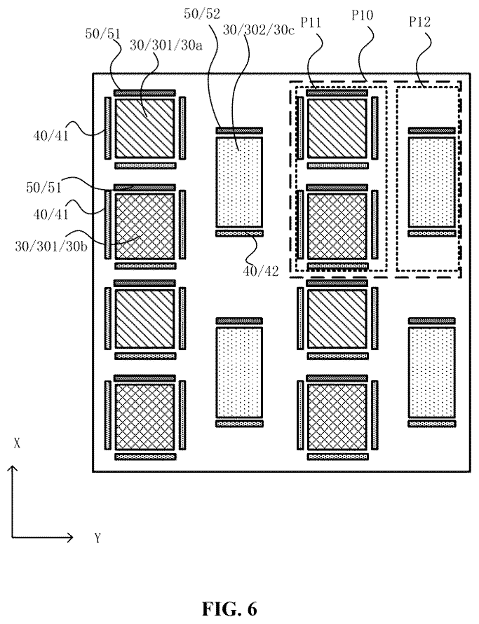

FIG. 6 is a planar schematic diagram of another exemplary display panel provided by the present disclosure. As shown in FIG. 6, in some embodiments, the light-emitting device 30 may also include a second light-emitting device 302, and the groove 40 located around the second light-emitting device 302 and adjacent to the second light-emitting device 302 may be referred to as a second groove 42, and the dimming structure 50 located around the second light-emitting device 302 and adjacent to the second light-emitting device 302 may be referred to as a second dimming structure 52. The vertical projections of the second groove 42 and the second dimming structure 52 on the plane where the substrate 10 is located may be both strip structures, and along the first direction X, the second groove 42 and the second dimming structure 52 may be respectively located at opposite sides of the second light-emitting device 302. The first direction X may be parallel to the plane where the substrate 10 is located.

Specifically, the light-emitting device 30 may also include a second light-emitting device 302. The groove 40 located around the second light-emitting device 302 and adjacent to the second light-emitting device 302 may be referred to as a second groove 42. The “around” mentioned here may refer to at least one side, and the “adjacent to” mentioned here may mean that there are no other grooves 40 between the two, and there are no other light-emitting devices 30 between the two. In other words, along the direction parallel to the plane where the substrate 10 is located, the second groove 42 may be arranged at at least one side of the second light-emitting device 302, and there may be no other grooves 40 or other light-emitting devices 30 between the second groove 42 and the second light-emitting device 302.

The dimming structure 50 located around the second light-emitting device 302 and adjacent to the second light-emitting device 302 may be referred to as a second dimming structure 52. The “around” mentioned here refers to at least one side, and the “adjacent to” mentioned here means that there may be no other dimming structures 50 between the two, and there may be no other light-emitting devices 30 between the two. In other words, along the direction parallel to the plane where the substrate 10 is located, the second dimming structure 52 may be arranged on at least one side of the second light-emitting device 302, and no other dimming structure 50 or other light-emitting device 30 may be arranged between the second dimming structure 52 and the second light-emitting device 302.

Along the first direction X, the second groove 42 and the second dimming structure 52 may be respectively located on opposite sides of the second light-emitting device 302. Because the arrangement of the groove 40 and the dimming structure 50 may be conducive to hindering the transmission of the lateral leakage current, the second groove 42 and the second dimming structure 52 may effectively block the transmission of the leakage current between the second light-emitting device 302 and the light-emitting device 30 adjacent to it along the first direction X, thereby improving the display effect.

Moreover, the arrangement of the second dimming structure 52 may adjust the large viewing angle light emitted by the second light-emitting device 302, effectively increase the number of small viewing angle light and positive viewing angle light, thereby effectively improving the light-emitting efficiency of the display panel and reducing power consumption. At the same time, the number of large viewing angle light arranged in the first direction X may be reduced, thereby realizing anti-peeping display in the first direction X.

It should be noted that the naming of the second light-emitting device 302 is only used to distinguish the setting mode of the groove 40 and the dimming structure 50 around the light-emitting device 30 and adjacent to the light-emitting device 30. The settings of the second light-emitting device 302 may also refer to the conventional setting mode in the field.

It should be noted that FIG. 6 exemplarily shows that the vertical projections of the second groove 42 and the second dimming structure 52 on the plane where the substrate 10 is located are both linear strip structures. In other embodiments of the present disclosure, the vertical projections of the second groove 42 and the second dimming structure 52 on the plane where the substrate 10 is located may also be non-linear strip structures, and the present disclosure does not make specific limitations on this.

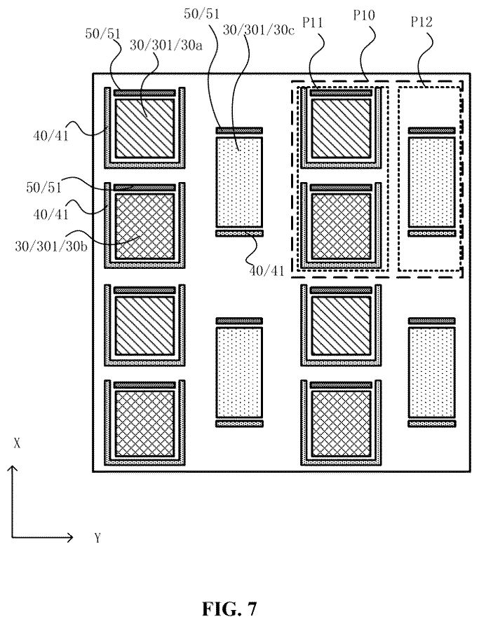

FIG. 7 is a top view of another exemplary display panel provided by the present disclosure. As shown in FIG. 7, in some embodiments, the display panel may include a plurality of light-emitting device groups P10. The light-emitting device groups P10 may include a first light-emitting device group P11 and a second light-emitting device group P12 arranged along the second direction Y. The first light-emitting device group P11 may include a first color light-emitting device 30a and a second color light-emitting device 30b arranged along the first direction X. The second light-emitting device group P12 may include a third color light-emitting device 30c. The first direction X and the second direction Y may intersect.

The first color light-emitting device 30a and the second color light-emitting device 30b may be both first light-emitting devices 301. The third color light-emitting device 30c may be the second light-emitting device 302.

Specifically, the light-emitting device group P10 may include a first light-emitting device group P11 and a second light-emitting device group P12 arranged along the second direction Y. The first light-emitting device group P11 may include a first color light-emitting device 30a and a second color light-emitting device 30b arranged along the first direction X. The first color light-emitting device 30a and the second color light-emitting device 30b may be both first light-emitting devices 301, that is, the arrangement of the groove 40 and the dimming structure 50 around the first color light-emitting device 30a and the second color light-emitting device 30b may adopt the arrangement of the groove 40 and the dimming structure 50 around the first light-emitting device 301. That is, the vertical projections of the first groove 41 located around the first color light-emitting device 30a and adjacent to the first color light-emitting device 30a and the first dimming structure 51 located around the first color light-emitting device 30a and adjacent to the first color light-emitting device 30a on the plane where the substrate 10 is located may form an annular structure. The vertical projection of the first color light-emitting device 30a on the plane where the substrate 10 is located may be located within the annular structure. Similarly, the vertical projections of the first groove 41 located around and adjacent to the second color light-emitting device 30b and the first dimming structure 51 located around and adjacent to the second color light-emitting device 30b on the plane where the substrate 10 is located may form an annular structure, and the vertical projection of the second color light-emitting device 30b on the plane where the substrate 10 is located may be located within the annular structure. The second light-emitting device group P12 may include a third color light-emitting device 30c, and the third color light-emitting device 30c may be the second light-emitting device 302, that is, the arrangement of the groove 40 and the dimming structure 50 around the third color light-emitting device 30c may adopt the arrangement of the groove 40 and the dimming structure 50 around the second light-emitting device 302. That is, along the first direction X, the second groove 42 located around and adjacent to the third color light-emitting device 30c and the second dimming structure 52 located around and adjacent to the third color light-emitting device 30c may be respectively located at two opposite sides of the third color light-emitting device 30c. Thus, in the display panel, a groove 40 and a dimming structure 50 may be provided between two adjacent light-emitting devices 30 along the first direction X, which may effectively block the transmission of leakage current between two adjacent light-emitting devices 30 along the first direction X. A groove 40 may be provided between two adjacent light-emitting devices 30 along the second direction Y, which may effectively block the transmission of leakage current between two adjacent light-emitting devices 30 along the second direction Y, and effectively improve the display effect.

At the same time, along the second direction Y, only one groove 40 is provided between the third color light-emitting device 30c and the adjacent first color light-emitting device 30a and second color light-emitting device 30b, which may effectively reduce the number of grooves 40 while blocking the transmission of leakage current between two adjacent light-emitting devices 30 along the second direction Y, thereby avoiding affecting the spacing between two adjacent openings 21 and affecting the size of the light-emitting device 30.

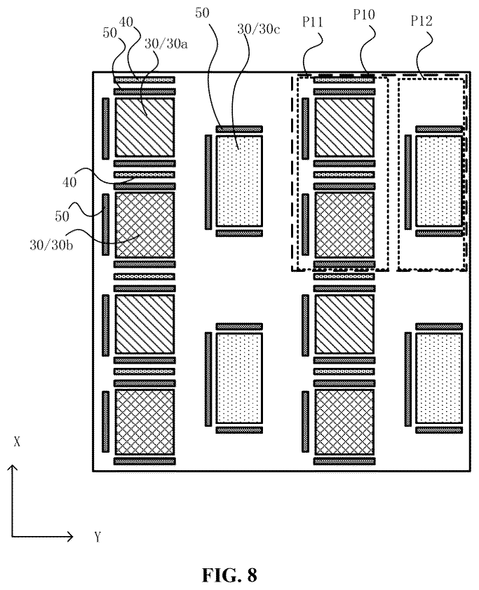

FIG. 8 is a top view of another exemplary display panel provided by the present disclosure. As shown in FIG. 8, in some embodiments, the display panel may include a plurality of light-emitting device groups P10. The light-emitting device group P10 may include a first light-emitting device group P11 and a second light-emitting device group P12 arranged along the second direction Y. The first light-emitting device group P11 may include a first color light-emitting device 30a and a second color light-emitting device 30b arranged along the first direction X, and the second light-emitting device group P12 may include a third color light-emitting device 30c. The first direction X and the second direction Y may intersect.

Along the first direction X, the light-emitting device 30 may have dimming structures 50 at both opposite sides, and along the second direction Y, the light-emitting device 30 may have dimming structures 50 at at least one side. Along the first direction X, a groove 40 and two dimming structures 50 may be arranged between adjacent first color light-emitting devices 30a and second color light-emitting devices 30b, and along the first direction X, the two dimming structures 50 may be respectively located at opposite sides of the groove 40.

Specifically, along the first direction X, dimming structures 50 may be provided at both opposite sides of the light-emitting device 30, and along the second direction Y, dimming structures 50 may be provided at at least one side of the light-emitting device 30. Accordingly, at least one dimming structure 50 may be provided between any two adjacent light-emitting devices 30, thereby effectively blocking the transmission of leakage current between the two adjacent light-emitting devices 30 and improving the display effect.

Moreover, the dimming structure 50 may adjust the large viewing angle light emitted by the light emitting device 30, effectively increase the number of small viewing angle light and positive viewing angle light, thereby effectively improving the light-emitting efficiency of the display panel and reducing power consumption. At the same time, the number of large viewing angle light in the first direction X and the second direction Y may be reduced, thereby realizing anti-peeping display in the first direction X and the second direction Y.

In the light-emitting device groups P10, the first light-emitting device group P11 may include a first color light-emitting device 30a and a second color light-emitting device 30b arranged along the first direction X, and the second light-emitting device group P12 may include a third color light-emitting device 30c. Along the first direction X, a groove 40 may be provided at both sides of the first color light-emitting device 30a, and the groove 40 may be adjacent to the first color light-emitting device 30a, that is, only one dimming structure 50 may be provided between the first color light-emitting device 30a and the groove 40 adjacent thereto, and no other groove 40 or light-emitting device 30 may be provided between the first color light-emitting device 30a and the groove 40 adjacent thereto. That is, in addition to the two dimming structures 50, a groove 40 may also provided between the adjacent first color light-emitting devices 30a and the second color light-emitting devices 30b, and along the first direction X, the two dimming structures 50 may be respectively located at opposite sides of the groove 40. Because the leakage current between the first color light-emitting device 30a and the second color light-emitting device 30b may be more serious, in addition to the two dimming structures 50, a groove 40 may be provided between the adjacent first color light-emitting devices 30a and the second color light-emitting devices 30b, which may effectively block the transmission of leakage current between the adjacent first color light-emitting devices 30a and the second color light-emitting devices 30b, thereby improving the display effect.

In one embodiment, the first color light-emitting device 30a may be a red light-emitting device, the second color light-emitting device 30b may be a green light-emitting device, and the third color light-emitting device 30c may be a blue light-emitting device. That is, in the light-emitting device group P10, the first light-emitting device group P11 may include a red light-emitting device and a green light-emitting device arranged along the first direction X, and the second light-emitting device group P12 may include a blue light-emitting device. In one embodiment, the vertical projection area of the red light-emitting device on the plane where the substrate 10 is located may be smaller than the vertical projection area of the green light-emitting device on the plane where the substrate 10 is located, and the vertical projection area of the green light-emitting device on the plane where the substrate 10 is located may be smaller than the vertical projection area of the blue light-emitting device on the plane where the substrate 10 is located. It should be noted that the specific values of the vertical projection areas of the red light-emitting device, the green light-emitting device and the blue light-emitting device on the plane where the substrate 10 is located may be set according to the actual display requirements, and the present disclosure will not repeat them. It should be noted that in other embodiments of the present disclosure, the first color light-emitting device 30a, the second color light-emitting device 30b and the third color light-emitting device 30c may also be light-emitting devices of other colors, and the present disclosure will not repeat them one by one here.

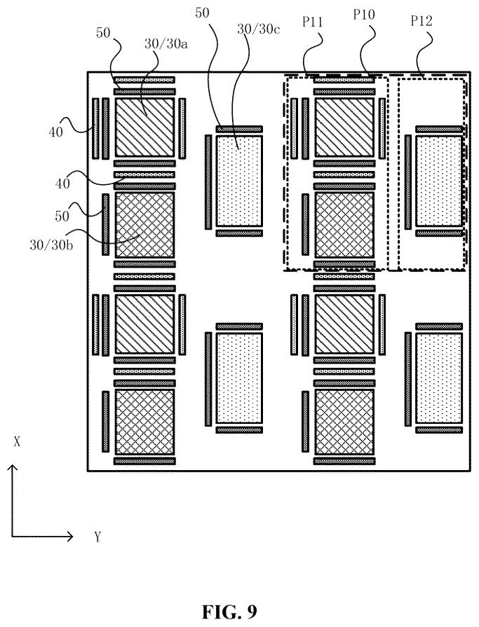

FIG. 9 is a planar schematic diagram of another exemplary display panel provided by the present disclosure. Referring to FIG. 9, in some embodiments, along the second direction Y, the first color light-emitting device 30a may be provided with grooves 40 at both sides opposite to each other.

Specifically, along the second direction Y, the first color light-emitting device 30a may be provided with grooves 40 at both sides opposite to each other, that is, in the second direction Y, in addition to the dimming structure 50, a groove 40 may also be provided between the adjacent first color light-emitting device 30a and the third color light-emitting device 30c. Because the leakage current phenomenon between the first color light-emitting device 30a and the third color light-emitting device 30c may also be relatively serious, in addition to the dimming structure 50, a groove 40 may also be provided between the adjacent first color light-emitting devices 30a and the third color light-emitting devices 30c, which may effectively block the transmission of leakage current between the adjacent first color light-emitting devices 30a and the third color light-emitting devices 30c and improve the display effect.

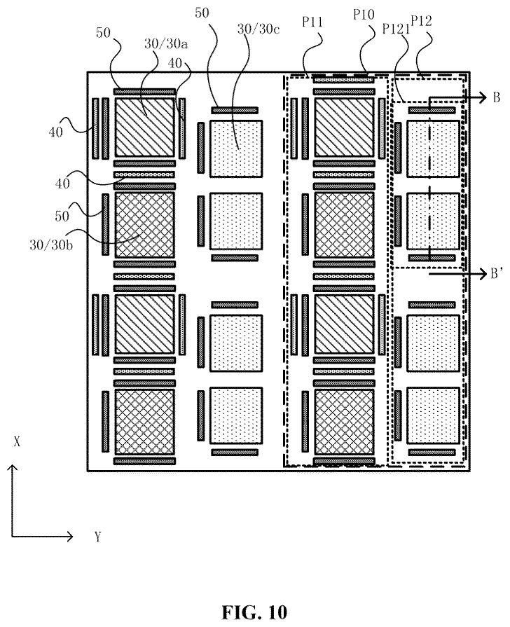

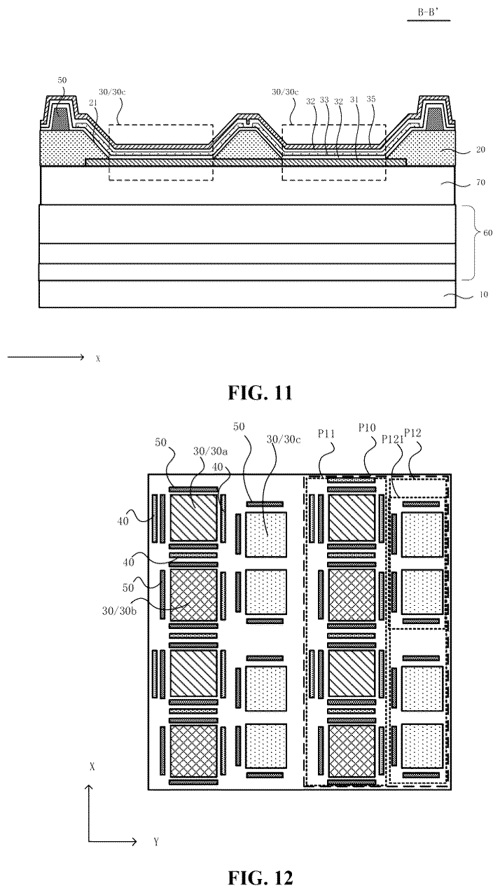

FIG. 10 is a top view of another display panel provided by the present disclosure, and FIG. 11 is a B-B′-sectional view of the display panel described in FIG. 10. As shown in FIG. 10 and FIG. 11, in some embodiments, the display panel may include a plurality of light-emitting device groups P10. The light-emitting device group P10 may include a first light-emitting device group P11 and a second light-emitting device group P12 arranged along the second direction Y. The first light-emitting device group P11 may include first color light-emitting devices 30a and second color light-emitting devices 30b arranged alternately in sequence along the first direction X, and the second light-emitting device group P12 may include at least one third color light-emitting device group P121. The third color light-emitting device group P121 may include at least two third color light-emitting devices 30c, and in the same third color light-emitting device group P121, the anodes 31 in each third color light-emitting device 30c may be connected. The first direction X and the second direction Y may intersect.

The gap between two adjacent third color light-emitting devices 30c in the same third color light-emitting device group P121 may not overlap the vertical projection of the plane where the substrate 10 is located and the vertical projection of the groove 40 on the plane where the substrate 10 is located. A groove 40 may be provided between the first color light-emitting device 30a and the third color light-emitting device 30c adjacent thereto.

Specifically, the display panel may include a plurality of light-emitting device groups P10. The light-emitting device group P10 may include a first light-emitting device group P11 and a second light-emitting device group P12 arranged along a second direction Y. The second light-emitting device group P12 may include at least one third color light-emitting device group P121. The third color light-emitting device group P121 may include at least two third color light-emitting devices 30c, and in the same third color light-emitting device group P121, the anodes 31 in each third color light-emitting device 30c may be connected, that is, each third color light-emitting device 30c in the same third color light-emitting device group P121 may be electrically connected to the same pixel circuit, that is, one third color light-emitting device group P121 may be a sub-pixel. Because the anodes 31 of each third color light emitting device 30c in the same third color light-emitting device group P121 may be connected, the vertical projection of the gap between two adjacent third color light-emitting devices 30c in the same third color light-emitting device group P121 on the plane where the substrate 10 is located may not overlap with the vertical projection of the groove 40 on the plane where the substrate 10 is located, that is, the area corresponding to the two adjacent third color light-emitting devices 30c in the same third color light-emitting device group P121 may not be provided with a groove 40, thereby avoiding the setting of the groove 40 affecting the connection between the anodes 31 of each third color light-emitting device 30c in the same third color light-emitting device group P121.

It should be noted that FIG. 10 exemplarily shows that the dimming structure 50 is not provided in the area corresponding to the two adjacent third color light-emitting devices 30c in the same third color light-emitting device group P121. In other embodiments of the present disclosure, the dimming structure 50 may also be provided in the area corresponding to the two adjacent third color light-emitting devices 30c in the same third color light-emitting device group P121, and the light emitted by the adjacent third color light-emitting device 30c may be adjusted by the dimming structure 50.

The first light-emitting device group P11 may include first color light-emitting devices 30a and second color light-emitting devices 30b arranged alternately in sequence along the first direction X. Because the leakage current between the first color light-emitting device 30a and the third color light-emitting device 30c may be more serious, a groove 40 may be provided between the first color light-emitting device 30a and the adjacent third color light-emitting device 30c, which may effectively block the transmission of the leakage current between the adjacent first color light-emitting device 30a and the third color light-emitting device 30c, thereby improving the display effect.

It should be noted that FIG. 10 and FIG. 11 exemplarily show that a third color light-emitting device group P121 may include two third color light-emitting devices 30c. In other embodiments of the present disclosure, a third color light-emitting device group P121 may also include three or more third color light-emitting devices 30c, which will not be described in detail in the present disclosure.

FIG. 12 is a top view of another exemplary display panel provided by the present disclosure. As shown in FIG. 12, in one embodiment, when the leakage current between the second color light-emitting device 30b and the third color light-emitting device 30c is serious, a groove 40 may be provided between the second color light-emitting device 30b and the third color light-emitting device 30c adjacent thereto, which may effectively block the transmission of the leakage current between the adjacent second color light-emitting device 30b and the third color light-emitting device 30c, thereby improving the display effect.

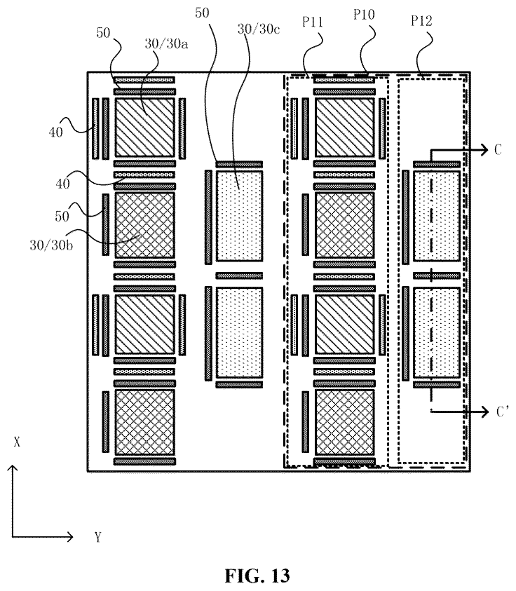

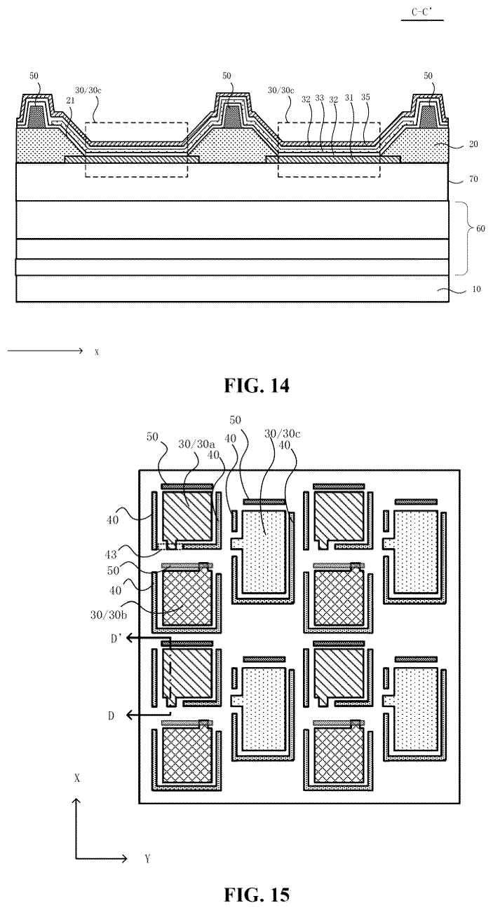

FIG. 13 is a top view of another exemplary display panel provided by the present disclosure, and FIG. 14 is a C-C′-sectional view of the display panel described in FIG. 13. As shown in FIG. 13 and FIG. 14, in some embodiments, the display panel may include a plurality of light-emitting device groups P10. The light-emitting device group P10 may include a first light-emitting device group P11 and a second light-emitting device group P12 arranged along the second direction Y. The first light-emitting device group P11 may include first color light-emitting devices 30a and second color light-emitting devices 30b arranged in sequence along the first direction X, and the second light-emitting device group P12 may include at least two third color light-emitting devices 30c arranged along the first direction X. In the same second light-emitting device group P12, the light-emitting layers 33 in each third color light-emitting device 30c may be connected. The first direction X and the second direction Y may intersect. In the same second light-emitting device group P12, only one groove 40 or one dimming structure 50 may be provided between two adjacent third color light-emitting devices 30c.

Specifically, the display panel may include a plurality of light-emitting device groups P10. The light-emitting device group P10 may include a first light-emitting device group P11 and a second light-emitting device group P12 arranged along the second direction Y. The second light-emitting device group P12 may include at least two third color light-emitting devices 30c arranged along the first direction X, and in the same second light-emitting device group P12, the light-emitting layers 33 in each third color light-emitting device 30c may be connected. That is, in the same second light-emitting device group P12, the light-emitting layers 33 in each third color light-emitting device 30c may be obtained by evaporation through the same mask opening, which may effectively reduce the difficulty of making the mask plate and reduce the production cost.

In the same second light-emitting device group P12, only one dimming structure 50 may be set between two adjacent third color light-emitting devices 30c. While blocking the transmission of leakage current between adjacent third color light-emitting devices 30c in the same second light-emitting device group P12, the number of dimming structures 50 may be reduced, thereby avoiding affecting the spacing between adjacent third color light-emitting devices 30c in the same second light-emitting device group P12, and causing the area of the light-emitting layer 33 in the third color light-emitting device 30c to be too large, effectively reducing the production cost.

It should be noted that FIG. 13 and FIG. 14 exemplarily show that in the same second light-emitting device group P12, only one dimming structure 50 may be set between two adjacent third-color light-emitting devices 30c. In other embodiments of the present disclosure, in the same second light-emitting device group P12, only one groove 40 may be set between two adjacent third-color light-emitting devices 30c. The specific structure may refer to the setting of the dimming structure 50 between two adjacent third-color light-emitting devices 30c in the same second light-emitting device group P12 in FIG. 13 and FIG. 14, which will not be repeated here.

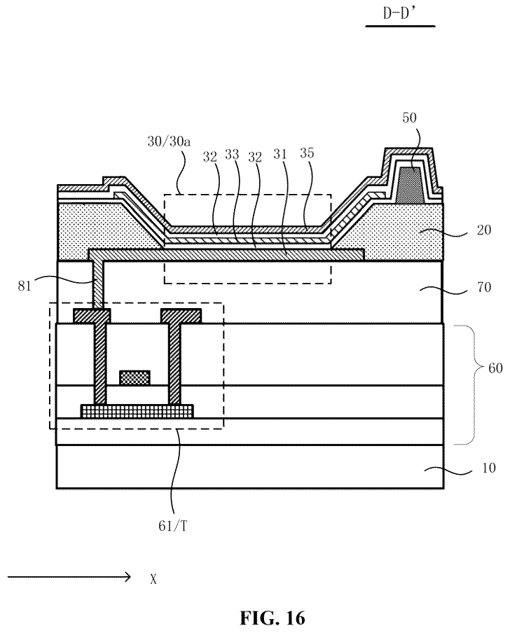

FIG. 15 is a top view of another exemplary display panel provided by the present disclosure, and FIG. 16 is a D-D′-sectional view of the display panel described in FIG. 15. As shown in FIG. 15 and FIG. 16, in some embodiments, the display panel may further include an array layer 60. The array layer 60 may be located between the substrate 10 and the pixel definition layer 20. The array layer 60 may include a plurality of pixel circuits 61, and the anode 31 of the light-emitting device 30 may be electrically connected to the pixel circuit 61 through the first via hole 81. The vertical projection of the groove 40 on the plane where the substrate 10 is located may not overlap with the vertical projection of the first via hole 81 on the plane where the substrate 10 is located.

Specifically, the display panel may further include an array layer 60 disposed between the substrate 10 and the pixel definition layer 20. The array layer 60 may include a pixel circuit 61. The anode 31 of the light-emitting device 30 may be electrically connected to the pixel circuit 61 through the first via hole 81. The pixel circuit 61 may drive the light-emitting device 30 electrically connected thereto to emit light.

Because the groove 40 may at least pass through the pixel definition layer 20 in the direction perpendicular to the plane where the substrate 10 is located, the vertical projection of the groove 40 on the plane where the substrate 10 is located may not overlap with the vertical projection of the first via hole 81 on the plane where the substrate 10 is located, that is, the groove 40 may not be set at the corresponding position of the first via hole 81 to avoid the setting of the groove 40 affecting the setting of the first via hole 81, thereby avoiding the setting of the groove 40 affecting the electrical connection between the pixel circuit 61 and the light-emitting device 30.

It should be noted that FIG. 16 only exemplarily shows that the pixel circuit 61 includes a transistor T, and the pixel circuit 61 may also include other structures. The specific circuit structure of the pixel circuit 61 may be set by those skilled in the art according to actual conditions, for example, it can be a 2T1C (two transistors and one capacitor), 7T1C, 8T1C or other circuits in the relevant technology, and the present disclosure does not make specific limitations on this.

Further, referring to FIG. 15 and FIG. 16, in some embodiments, the display panel may further include a cut-off area 43, and the groove 40 may be cut off at the cut-off area 43. The vertical projection of the cut-off area 43 on the plane where the base substrate 10 is located may at least partially overlap with the vertical projection of the first via hole 81 on the plane where the substrate 10 is located.

Specifically, the display panel may further include a cut-off area 43, and the groove 40 may be cut-off at the cut-off area 43, that is, the groove 40 may not be set in the area corresponding to the cut-off area 43. The vertical projection of the cut-off area 43 on the plane where the substrate 10 is located may at least partially overlap with the vertical projection of the first via hole 81 on the plane where the substrate 10 is located, that is, the groove 40 may be designed to be cut-off in the area corresponding to the first via hole 81. Accordingly, the vertical projection of the groove 40 on the plane where the substrate 10 is located may not overlap with the vertical projection of the first via hole 81 on the plane where the substrate 10 is located, that is, the groove 40 may be not set at the corresponding position of the first via hole 81 to avoid the setting of the groove 40 affecting the setting of the first via hole 81, thereby avoiding the setting of the groove 40 affecting the electrical connection between the pixel circuit 61 and the light-emitting device 30.

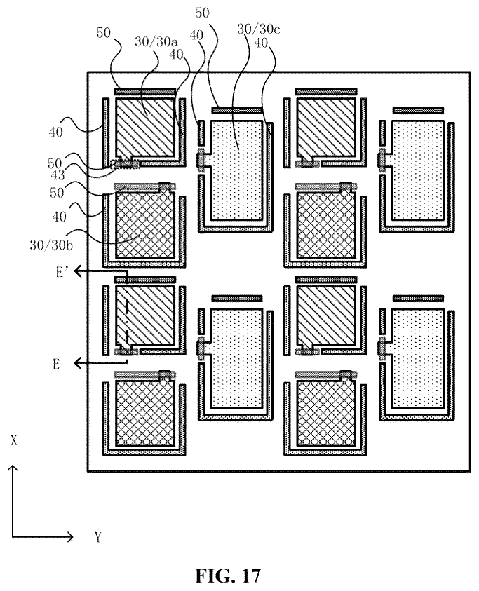

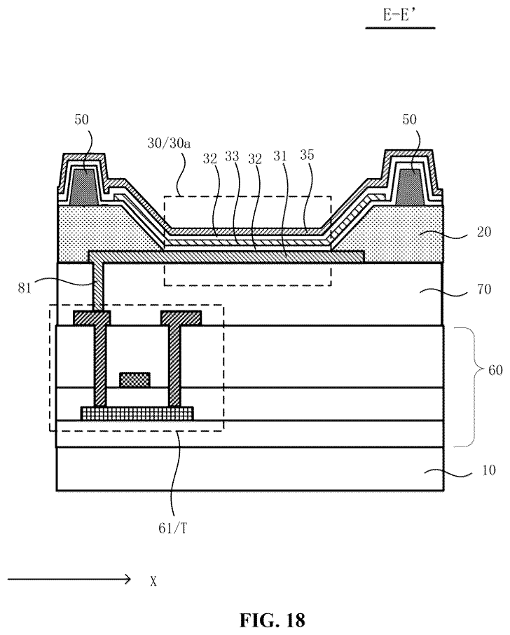

FIG. 17 is a top view of another exemplary display panel provided by the present disclosure, and FIG. 18 is an E-E′-sectional view of the display panel described in FIG. 17. As shown in FIG. 17 and FIG. 18, in some embodiments, the vertical projection of the dimming structure 50 on the plane where the base substrate 10 is located may at least partially overlap with the vertical projection of the first via hole 81 on the plane where the substrate 10 is located.

Specifically, because the groove 40 may at least pass through the pixel definition layer 20 in the direction perpendicular to the plane where the substrate 10 is located, the vertical projection of the groove 40 on the plane where the substrate 10 is located may not overlap with the vertical projection of the first via hole 81 on the plane where the substrate 10 is located, that is, the groove 40 may not be set at the corresponding position of the first via hole 81 to avoid the setting of the groove 40 affecting the setting of the first via hole 81. The dimming structure 50 may be located at the side of the pixel definition layer 20 away from the substrate 10 such that the vertical projection of the dimming structure 50 on the plane where the substrate 10 is located and the vertical projection of the first via hole 81 on the plane where the substrate 10 is located may at least partially overlap, that is, the dimming structure 50 may be set in the area corresponding to the first via hole 81, and the setting of the dimming structure 50 and the setting of the first via hole 81 may not affect each other. That is, the dimming structure 50 may be set around the light-emitting device 30 and in the area where the groove 40 cannot be set, and the transmission of leakage current between the light-emitting device 30 and the light-emitting device 30 adjacent to it may be blocked by the dimming structure 50, thereby improving the display effect.

In other embodiments, the vertical projection of the dimming structure 50 on the plane where the substrate 10 is located may at least partially overlap with the vertical projection of the cut-off area 43 on the plane where the substrate 10 is located.

Specifically, the groove 40 may be cut-off at the cut-off area 43, that is, the groove 40 may not be set in the area corresponding to the cut-off area 43, and the vertical projection of the cut-off area 43 on the plane where the substrate 10 is located may at least partially overlap with the vertical projection of the first via hole 81 on the plane where the substrate 10 is located, that is, the groove 40 may be cut-off in the area corresponding to the first via hole 81 such that the vertical projection of the groove 40 on the plane where the substrate 10 is located may not overlap with the vertical projection of the first via hole 81 on the plane where the substrate 10 is located, and the vertical projection of the dimming structure 50 on the plane where the substrate 10 is located may at least partially overlap with the vertical projection of the truncation area 43 on the plane where the substrate 10 is located, that is, the dimming structure 50 may be set at the cut-off area of the groove 40, and the transmission of leakage current between the light-emitting device 30 and the light-emitting device 30 adjacent to it may be blocked by the dimming structure 50, thereby improving the display effect.

In one embodiment, the dimming structure 50 and the first via hole 81 may be located at the same side of the light-emitting device 30, and the groove 40 may not be provided on the side of the light-emitting device 30 provided with the first via hole 81. That is, the dimming structure 50 may also be directly provided at the side of the light-emitting device 30 provided with the first via hole 81, and the dimming structure 50 may be used to block the transmission of leakage current between the light-emitting device 30 and the light-emitting device 30 adjacent thereto, thereby improving the display effect. The groove 40 may not be provided at the side of the light-emitting device 30 provided with the first via hole 81, thereby avoiding the setting of the groove 40 affecting the setting of the first via hole 81, thereby avoiding the setting of the groove 40 affecting the electrical connection between the pixel circuit 61 and the light-emitting device 30.

Further, referring to FIG. 1 and FIG. 2, in some embodiments, the dimming structure 50 may include an intersecting first side surface 53 and a first bottom surface 54. The first side surface 53 may be the surface of the dimming structure 50 adjacent to the adjacent light-emitting device 30, the first bottom surface 54 may be the surface of the dimming structure 50 adjacent to the pixel definition layer 20, and the angle between the first side surface 53 and the first bottom surface 54 may be less than 90°.

Specifically, the dimming structure 50 may include a first side surface 53 and a first bottom surface 54 intersecting each other. The surface of the dimming structure 50 adjacent to the adjacent light-emitting device 30 may be the first side surface 53, and the surface of the dimming structure 50 adjacent to the pixel definition layer 20 may be the first bottom surface 54. The angle between the first side surface 53 and the first bottom surface 54 may be less than 90°, that is, in the direction from the substrate 10 to the pixel definition layer 20, the first side surface 53 may gradually tilt away from the adjacent light-emitting device 30 such that, after the wide viewing angle light emitted by the light emitting device 30 is reflected toward the first side surface 53, the reflected light may be deflected toward the direction adjacent to the normal viewing angle, which may be conducive to increasing the number of normal viewing angle light, and effectively improving the luminous efficiency of the display panel and reducing power consumption.

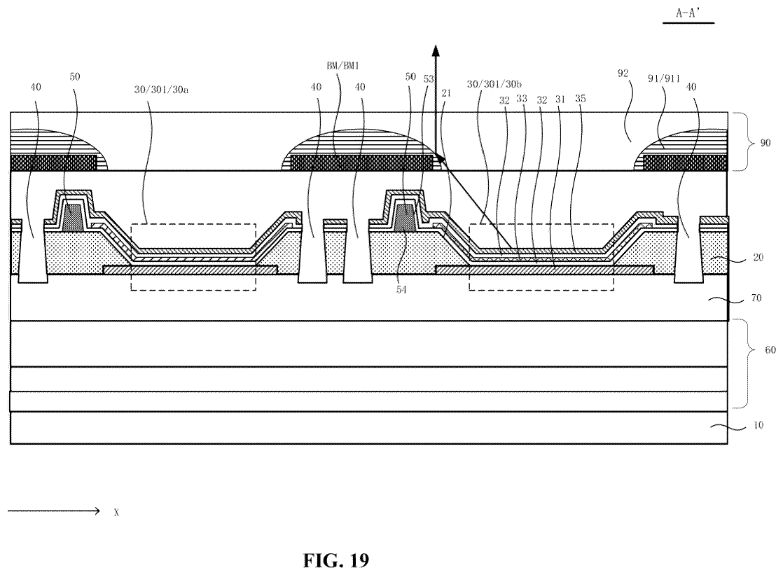

FIG. 19 is another A-A′-sectional view of the display panel described in FIG. 1. Referring to FIG. 1 and FIG. 19, in some embodiments, the display panel may further include a light-shielding layer BM. The light-shielding layer BM may be located on the side of the dimming structure 50 away from the substrate 10. The light-shielding layer BM may include a plurality of light-shielding portions BM1, and the vertical projection of the dimming structure 50 on the plane where the substrate 10 is located may be located within the vertical projection of the light-shielding portion BM1 on the plane where the substrate 10 is located.

Specifically, the display panel may further include a light-shielding layer BM. The light-shielding layer BM may be located on the side of the dimming structure 50 away from the substrate 10. The light-shielding layer BM may include a plurality of light-shielding portions BM1. In one embodiment, a mesh structure having a plurality of meshes may be formed between the light-shielding portions BM1 in the light-shielding layer BM. The meshes may correspond to the openings 21 one by one. Along a direction perpendicular to the plane where the substrate 10 is located, the mesh and the corresponding opening 21 may at least partially overlap, the light-shielding portion BM1 may not overlap with the light-emitting device 30. The vertical projections of the dimming structure 50 and the groove 40 on the plane where the base substrate 10 is located may be both located within the vertical projection of the light-shielding portion BM1 on the plane where the base substrate 10 is located, which may be conducive to reducing the influence of the dimming structure 50 and the groove 40 on the aperture ratio of the display panel.

Referring to FIG. 1 and FIG. 19, in some embodiments, the display panel may further include a light-adjustment layer 90. The light-adjustment layer 90 may be located on the side of the light-shielding layer BM away from the substrate 10.

The light-adjustment layer 90 may include a first dimming layer 91 and a second dimming layer 92. The second dimming layer 92 may be located on the side of the first dimming layer 91 away from the light-shielding layer BM. The first dimming layer 91 may include a plurality of first dimming members 911. The first dimming members 911 may at least partially cover the light-shielding member BM1. The first dimming members 911 may be convex structures protruding in the direction away from the substrate 10. The vertical projection of the first dimming members 911 on the plane where the substrate 10 is located may not overlap with the vertical projection of the light-emitting device 30 on the plane where the substrate 10 is located, and the second dimming layer 92 may cover the first dimming members 911. The refractive index of the first dimming member 911 may be lower than the refractive index of the second dimming layer 92.

Specifically, the display panel may further include a light-adjustment layer 90, which may be located at the side of the light-shielding layer BM away from the substrate 10. The light-adjustment layer 90 may include a first dimming layer 91 and a second dimming layer 92. The second dimming layer 92 may be located at the side of the first dimming layer 91 away from the light-shielding layer BM. The first dimming layer 91 may include a plurality of first dimming members 911, and the first dimming member 911 may be a protruding structure protruding in the direction away from the substrate 10. The second dimming layer 92 may cover the first dimming member 911, and the refractive index of the first dimming member 911 may be lower than the refractive index of the second dimming layer 92 such that the interface where the first dimming member 911 and the second dimming layer 92 contact, that is, the sidewall of the first dimming member 911, may form a total reflection interface, and the wide viewing angle light emitted by the light-emitting device 30 may be totally reflected when it is directed to the sidewall of the first dimming member 911, thereby changing the transmission direction of the light. Accordingly, the light may be deflected toward the positive viewing angle direction, which may be conducive to increasing the number of positive viewing angle light, and effectively improving the light-emitting efficiency of the display panel and reducing power consumption.

In one embodiment, the surface of the first dimming member 911 away from the substrate 10 may be a curved structure, and the first dimming member 911 may also be a trapezoidal column structure. In other embodiments of the present disclosure, the first dimming member 911 may also be other structures, and the present disclosure does not specifically limit this.

It should be noted that in some embodiments, the display panel may also include a protective layer (not shown in the figure) located on the light-adjustment layer. In one embodiment, the protective layer may be a film layer on the outermost side of the display panel, which may be a protective cover plate or cover film. The protective layer may be bonded to the film layer inside the adjacent display panel by optically clear adhesive (OCA).

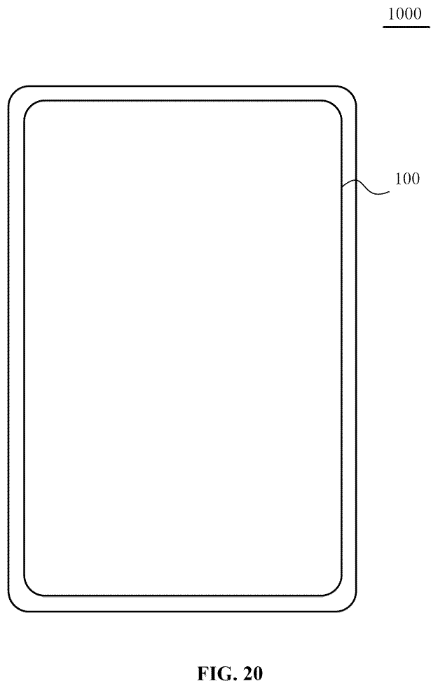

The present disclosure also provides a display device. FIG. 20 is a planar schematic diagram of an exemplary display device according to various disclosed embodiments of the present disclosure. As shown in FIG. 20, the display device 1000 may include a display panel 100 provided by any of the above embodiments. The embodiment provided in FIG. 20 only takes a mobile phone as an example to illustrate the display device. It can be understood that the display device provided in the embodiments of the present disclosure may be any electronic product with a display function, including but not limited to the following categories: mobile phones, televisions, laptops, desktop displays, tablet computers, digital cameras, smart bracelets, smart glasses, car displays, medical equipment, industrial control equipment, or touch interactive terminals, etc., and the embodiments of the present disclosure do not specifically limit this.

The display device 1000 provided in the embodiment of the present disclosure may include the same technical features as the display panel 100 provided in the above embodiments, so it may also solve the same technical problems and achieve the same technical effects.

The technical solutions provided by the present disclosure may include the following advantages.

In the display panel provided by the present disclosure, a groove may be provided at at least one side of the light-emitting device in a direction parallel to the plane where the substrate is located, and the groove may at least pass through the pixel definition layer in a direction perpendicular to the plane where the substrate is located. Accordingly, when the common layer is subsequently evaporated, the setting of the groove may increase the path length of the common layer, and the inclined surface of the inner wall of the groove may cause the thickness of the common layer to be thinned, and even cause the common layer to be cut off, thereby effectively hindering the transmission of lateral leakage current, reducing the problem of sub-pixel light leaking, and improving the display effect. Along the direction parallel to the plane where the substrate is located, at least one side of the light-emitting device may also be provided with a dimming structure, and the dimming structure may be located on the side of the pixel definition layer away from the substrate. Accordingly, when the common layer is subsequently evaporated, the portion of the common layer covering the dimming structure may be a raised structure, and the setting of the dimming structure may increase the path length of the common layer, and the inclined surface of the dimming structure may cause the thickness of the common layer to be thinned, thereby effectively hindering the transmission of lateral leakage current, reducing the problem of sub-pixel light leaking, and improving the display effect. At the same time, when the wide-angle light emitted by the light-emitting device is directed to the dimming structure adjacent to it, the dimming structure may change the light path of the wide-angle light, so that the wide-angle light may be converted into a small-angle light or a positive-angle light, effectively increasing the number of small-angle light and positive-angle light. Because the user's human eye observes the display panel usually in the positive-angle direction or the small-angle direction, the increase in the number of small-angle light and positive-angle light may effectively improve the light-emitting efficiency of the display panel and reduce power consumption. The setting of the dimming structure may effectively reduce the number of wide-angle light, thus users at a wide-angle position may not view the display screen of the display panel, thereby realizing the anti-peeping function.

Correspondingly, the display device provided by the present disclosure may also include the above-mentioned technical effects.

It should be noted that in this disclosure, relational terms such as “first” and “second” are only used to distinguish one entity or operation from another entity or operation, and do not necessarily require or imply that there is any such actual relationship or order between these entities or operations. Moreover, the terms “include”, “comprise” or any other variants thereof are intended to cover non-exclusive inclusion. Thus, a process, method, article or device including a series of elements includes not only those elements, but also includes other elements that are not explicitly listed, or also includes elements inherent to such a process, method, article or device. In the absence of further restrictions, an element defined by the sentence “comprising a . . . ” does not exclude the presence of other identical elements in the process, method, article or device comprising the element.

The above is only a specific implementation of the present disclosure, so that those skilled in the art can understand or implement the present disclosure. Various modifications to these embodiments will be obvious to those skilled in the art, and the general principles defined herein can be implemented in other embodiments without departing from the spirit or scope of the present disclosure. Therefore, the present disclosure will not be limited to the embodiments described herein, but will conform to the widest scope consistent with the principles and novel features disclosed herein.

What is claimed is:

1. A display panel, comprising:
a substrate;
a pixel definition layer, located at one side of the substrate and including a plurality of openings;
a plurality of light-emitting devices corresponding to the plurality of openings one by one and each light-emitting device being at least partially located in a corresponding opening of the plurality of openings;
a groove at least passing through the pixel definition layer along a direction perpendicular to a plane where the substrate is located; and
a dimming structure located at a side of the pixel definition layer away from the substrate,
wherein, along the direction parallel to the plane where the substrate is located, at least one side of the light-emitting device is provided with the groove, and at least one side of the light-emitting device is provided with the dimming structure.

2. The display panel according to claim 1, wherein:
at least one groove and/or at least one dimming structure is arranged between two adjacent light-emitting devices of the plurality of light-emitting devices.

3. The display panel according to claim 1, wherein:
a vertical projection of the groove on the plane where the substrate is located does not overlap with a vertical projection of the dimming structure on the plane where the substrate is located.

4. The display panel according to claim 2, wherein:
a light-emitting device includes a first light-emitting device;
the groove located around the first light-emitting device and adjacent to the first light-emitting device is a first groove;
the dimming structure located around the first light-emitting device and adjacent to the first light-emitting device is a first dimming structure;
vertical projections of the first groove and the first dimming structure on the plane where the substrate is located form an annular structure; and
a vertical projection of the first light-emitting device on the plane where the substrate is located is located within the annular structure.

5. The display panel according to claim 4, wherein:
the plurality of light-emitting devices in the display panel are all first light-emitting devices.

6. The display panel according to claim 4, wherein:
the vertical projection of the first groove on the plane where the substrate is located is a semi-annular structure including a first notch;
along the first direction, the first notch is located at one side of the first light-emitting device;
the first direction is parallel to the plane where the substrate is located;
a vertical projection of the first dimming structure on the plane where the substrate is located is a strip structure; and
along the first direction, the first dimming structure and the first notch are located at a same side of the first light-emitting device.

7. The display panel according to claim 6, wherein:
a length of the first dimming structure along the second direction is greater than a length of the first notch along the second direction;
along the first direction, the first notch is located at a side of the first dimming structure away from the first light-emitting device; and
the first direction and the second direction intersect.

8. The display panel according to claim 4, wherein:
the first groove includes a plurality of mutually separated first sub-members;
a vertical projection of a first sub-member of the plurality of first sub-members on the plane where the substrate is located is a strip structure;
along the first direction, one first dimming structure and one first sub-member are respectively located at two opposite sides of the first light-emitting device;
along the second direction, two first sub-members are respectively located at two opposite sides of the first light-emitting device; and
the first direction and the second direction intersect.

9. The display panel according to claim 4, wherein:
the light-emitting device also includes a second light-emitting device;
the groove located around the second light-emitting device and adjacent to the second light-emitting device is a second groove;
the dimming structure located around the second light-emitting device and adjacent to the second light-emitting device is a second dimming structure;
vertical projections of the second groove and the second dimming structure on the plane where the substrate is located are both strip structures;
along the first direction, the second groove and the second dimming structure are respectively located at two opposite sides of the second light-emitting device; and
the first direction is parallel to the plane where the substrate is located.

10. The display panel according to claim 9, comprising:
a plurality of light-emitting device groups,
wherein:
a light-emitting device group of the plurality of light-emitting groups includes a first light-emitting device group and a second light-emitting device group arranged along a second direction;
the first light-emitting device group includes a first color light-emitting device and a second color light-emitting device arranged along the first direction;
the second light-emitting device group includes a third color light-emitting device;
the first direction and the second direction intersect;
the first color light-emitting device and the second color light-emitting device are both the first light-emitting devices; and
the third color light-emitting device is the second light-emitting device.

11. The display panel according to claim 2, comprising:
a plurality of light-emitting device groups,
wherein:
a light-emitting device group of the plurality of light-emitting device groups includes a first light-emitting device group and a second light-emitting device group arranged along the second direction;
the first light-emitting device group includes a first color light-emitting device and a second color light-emitting device arranged along the first direction;
the second light-emitting device group includes a third color light-emitting device;
the first direction and the second direction intersect;
along the first direction, the dimming structure is provided at both opposite sides of the light-emitting device;
along the second direction, the dimming structure is provided at at least one side of the light-emitting device;
along the first direction, one groove and two dimming structures are provided between adjacent first color light-emitting devices and second color light-emitting devices;
along the first direction, the two dimming structures are respectively located at opposite sides of the groove; or
along the second direction, two opposite sides of the first color light-emitting device are both arranged with the grooves.

12. The display panel according to claim 1, comprising:
a plurality of light-emitting device groups,
wherein:
a light-emitting device group of the plurality of light-emitting device groups includes a first light-emitting device group and a second light-emitting device group arranged along the second direction;
the first light-emitting device group includes first color light-emitting devices and second color light-emitting devices arranged alternately in sequence along the first direction;
a second light-emitting device group includes at least one third color light-emitting device group;
the at least one third color light-emitting device group includes at least two third color light-emitting devices;
in a same third color light-emitting device group, anodes of all third color light-emitting devices are connected;
the first direction and the second direction intersect;
a gap between two adjacent third color light-emitting devices in the same third color light-emitting device group does not overlap with a vertical projection of the groove on the plane where the substrate is located; and
the groove is arranged between the first color light-emitting device and the third color light-emitting device adjacent thereto.

13. The display panel according to claim 1, comprising:
a plurality of light-emitting device groups,
wherein:
a light-emitting device group of the plurality of light-emitting device groups includes a first light-emitting device group and a second light-emitting device group arranged along a second direction;
the first light-emitting device group includes first color light-emitting devices and second color light-emitting devices arranged in sequence and staggered along the first direction;
the second light-emitting device group includes at least two third color light-emitting devices arranged along the first direction;
in a same second light-emitting device group, light-emitting layers of all third color light-emitting devices are connected;
the first direction and the second direction intersect; and
in a same second light-emitting device group, only one groove or one dimming structure is provided between two adjacent third color light-emitting devices.

14. The display panel according to claim 1, further comprising:
an array layer, located between the substrate and the pixel definition layer,
wherein:
the array layer includes a plurality of pixel circuits, and an anode of the light-emitting device is electrically connected to a pixel circuit of the plurality of pixel circuits through a first via hole; and
a vertical projection of the groove on the plane where the substrate is located does not overlap with a vertical projection of the first via hole on the plane where the substrate is located.

15. The display panel according to claim 14, further comprising:
a cut-off area,
wherein the groove is cut off at the cut-off area; and a vertical projection of the cut-off area on the plane where the substrate is located at least partially overlaps with the vertical projection of the first via hole on the plane where the substrate is located; or
a vertical projection of the dimming structure on the plane where the substrate is located at least partially overlaps with the vertical projection of the first via hole on the plane where the substrate is located.

16. The display panel according to claim 1, wherein:
the dimming structure includes a first side surface and a first bottom surface intersecting each other;
the first side surface is a surface of the dimming structure adjacent to the light-emitting device;
the first bottom surface is a surface of the dimming structure adjacent to the pixel definition layer; and
an angle between the first side surface and the first bottom surface is less than 90°.

17. The display panel according to claim 1, wherein:
a material of the dimming structure includes a reflective material.

18. The display panel according to claim 1, further comprising:
a light-shielding layer, located on a side of the dimming structure away from the substrate,
wherein:
the light-shielding layer includes a plurality of light-shielding members; and
vertical projections of the dimming structure and the groove on the plane where the substrate is located are both located within vertical projections of the light-shielding members on the plane where the substrate is located.

19. The display panel according to claim 20, further comprising:
a light-adjustment layer, located at a side of the light-shielding layer away from the substrate,
wherein:
the light-adjustment layer includes a first dimming layer and a second dimming layer located at a side of the first dimming layer away from the light-shielding layer;
the first dimming layer includes a plurality of first dimming members at least partially covering the light-shielding members;
a first dimming member of the plurality of first dimming members is a protruding structure protruding in a direction away from the substrate;
a vertical projection of the first dimming member on the plane where the base substrate is located does not overlap with a vertical projection of the light-emitting device on the plane where the substrate is located;
the second dimming layer covers the first dimming member; and
a refractive index of the first dimming member is lower than a refractive index of the second dimming layer.

20. A display device, comprising:
a display panel including:
a substrate;
a pixel definition layer, located at one side of the substrate and including a plurality of openings;
a plurality of light-emitting devices corresponding to the plurality of openings one by one and each light-emitting device being at least partially located in a corresponding opening of the plurality of openings;
a groove at least passing through the pixel definition layer along a direction perpendicular to a plane where the substrate is located; and
a dimming structure located at a side of the pixel definition layer away from the substrate,
wherein, along the direction parallel to the plane where the substrate is located, at least one side of the light-emitting device is provided with the groove, and at least one side of the light-emitting device is provided with the dimming structure.
